(19) United States
(12) Patent Application Publication
(10) Pub. No.: US 2005/0132949 A1
(43) Pub. Date: Jun. 23, 2005

(54) Forming carbon nanotubes by iterating nanotube growth and post-treatment steps

(76) Inventors: Sung Gu Kang, San Jose, CA (US); Craig Bae, Campbell, CA (US)

Correspondence Address: FENWICK & WEST LLP, SILICON VALLEY CENTER, 801 CALIFORNIA STREET, MOUNTAIN VIEW, CA, 94041, US

(21) Appl. No.: 11/034,442

(22) Filed: Jan. 10, 2005

Related U.S. Application Data
(63) Continuation-in-part of application No. 10/302,126, filed on Nov. 22, 2002, now Pat. No. 6,841,002.
(63) Continuation-in-part of application No. 10/302,206, filed on Nov. 22, 2002, now Pat. No. 6,841,003.

(51) Int. Cl. C30B 7/00; C30B 21/02; C30B 28/06

(52) U.S. Cl. 117/68

(57) ABSTRACT

Carbon nanotubes are formed on a surface of a substrate using a plasma chemical deposition process. The nanotubes are grown by plasma enhanced chemical vapor deposition using a source gas and a plasma and are then purified by plasma etching using a purification gas. These growth and purification steps are repeated without evacuating the chamber and without turning off the plasma. After the nanotubes are grown, a post-treatment step is performed on the nanotubes by etching using the plasma. During the transition from the nanotube growth step to the post treatment step, the pressure in the plasma process chamber is stabilized without turning off the plasma. The entire process or a portion thereof may be iterated to achieve a carbon nanotube layer having highly uniform physical characteristics. Additionally, the etching in the post-treatment step may be reduced each iteration.

### CROSS REFERENCE TO RELATED APPLICATIONS

This application is a continuation-in-part of U.S. application Ser. No. 10/302,126, filed Nov. 22, 2002, now U.S. Pat. No. 6,841,002, and is a continuation-in-part of U.S. application Ser. No. 10/302,206, filed Nov. 22, 2002, now U.S. Pat. No. 6,841,003, both of which are incorporated by reference in their entirety. This application is also related to U.S. application Ser. No. 10/226,873, filed Aug. 22, 2002, which is incorporated by reference in its entirety.

### BACKGROUND

1. Field of the Invention

This invention relates generally to forming carbon nanotubes, and in particular to forming purified carbon nanotubes for an electron-emitting device.

2. Background of the Invention

Carbon has four crystalline states, including diamond, graphite, fullerene and carbon nanotubes. Among these states, carbon nanotubes exhibit a number of remarkable electrical and mechanical properties. Their properties make nanotubes very desirable for use in modem electronic devices, such as field emissive displays. Carbon nanotubes were originally created by means of an electric arc discharge between two graphite rods. However, this technique for forming nanotubes is not efficient and requires a complicated post-treatment and/or purification procedures.

Carbon nanotubes can be also grown on a substrate using plasma enhanced chemical vapor deposition (PECVD), as described for example in U.S. Pat. No. 6,331,209, which is incorporated by reference in its entirety. According to the conventional method disclosed in this patent, carbon nanotubes are grown on a substrate using PECVD at a high plasma density. Specifically, the conventional technique includes: growing a carbon nanotube layer on a substrate to have a predetermined thickness by plasma deposition; purifying the carbon nanotube layer by plasma etching; and repeating the growth and the purification of the carbon nanotube layer. For the purifying, a halogen-containing gas (e.g., a carbon tetrafluoride gas), fluorine, or an oxygen-containing gas is used as a source gas.

It should be noted that according to the conventional method for growing carbon nanotubes, after each nanotube growth step and before the nanotube purification step, the plasma in the process chamber has to be turned off and the process chamber has to be purged and evacuated. Subsequently, the pressure of the purifying gas needs to be stabilized and the plasma needs to be turned back on. These multiple steps, which must be completed after the nanotubes have been grown and before they are purified, make the conventional process for forming carbon nanotubes unduly expensive and time consuming.

Accordingly, what is needed is a technique for forming carbon nanotubes utilizing a fewer number of process steps.

### SUMMARY OF THE INVENTION

Embodiments of the present invention are therefore directed to methods and systems that substantially obviate one or more of the above and other problems associated with conventional techniques for forming carbon nanotubes. Consistent with exemplary embodiments of the present invention, methods for forming carbon nanotubes are provided.

In one embodiment, a method for forming carbon nanotubes on a substrate in a process chamber includes growing a plurality of carbon nanotubes by plasma enhanced chemical vapor deposition using a source gas and a plasma. The grown carbon nanotubes are then purified by plasma etching using a purification gas, after which the growing and purifying steps can be repeated. Beneficially, the process chamber is not evacuated and the plasma is not turned off between the growing and purifying steps. Once the carbon nanotubes are grown and purified through the successive steps described, the nanotubes are post-treated by etching using the plasma. Again, the post-treatment is performed without turning off the plasma after the carbon nanotubes are grown.

A number of process variables may be chosen to improve the result of the grown carbon nanotubes. For example, the substrate surface may be coated with a catalytic material. In addition, a buffer layer may be provided between the substrate and the catalytic layer. During the growing, a hydrocarbon gas may be used as a source gas for the plasma chemical deposition, and a hydrogen-containing carbon gas may be used as an additive gas for enhancing the purification process. Alternatively, during the purification process, the additive gas (e.g., a hydrogen-containing gas) that is used during the growing of the carbon nanotubes is also used continuously as a source gas for the plasma etching process. Additionally, a plasma source gas may be added as an additive to the source gas for the plasma chemical deposition.

In another embodiment, a method of forming carbon nanotubes includes growing a plurality of carbon nanotubes by chemical vapor deposition using a plasma and then, without shutting off the plasma after the carbon nanotubes are grown, post-treating the grown carbon nanotubes by etching. The etching of the post-treatment step results in the shortening of at least some of the carbon nanotubes. The growing and post-treating steps are then repeated. In one embodiment, a first iteration of the post-treating step etches more carbon nanotube length than a second and/or subsequent iterations of the post-treating step.

It is to be understood that both the foregoing and the following descriptions are exemplary and explanatory only, and they are therefore not intended to limit the claimed invention in any manner except to the extent they are included as limitations in the claims.

### BRIEF DESCRIPTION OF THE DRAWINGS

FIG. 1 is a cross-sectional view of a substrate for use in the formation of carbon nanotubes, in accordance with an embodiment of the invention.

FIG. 2 is a cross-sectional view of a substrate during a growth stage of a carbon nanotube formation process, in accordance with an embodiment of the invention.

FIG. 3 is a cross-sectional view of a purification stage of the carbon nanotube formation process, in accordance with an embodiment of the invention.

FIG. 4 is a cross-sectional view of a substrate having a purified carbon nanotube layer formed thereon, in accordance with an embodiment of the invention.

FIG. 5 is a cross-sectional view of a post-treatment stage of the carbon nanotube formation process, in accordance with an embodiment of the invention.

FIG. 6 is a cross-sectional view of a substrate having a purified and post-treated carbon nanotube layer formed thereon, in accordance with an embodiment of the invention.

### DETAILED DESCRIPTION OF THE PREFERRED EMBODIMENTS

In various embodiments of the invention, carbon nanotubes are formed on a surface of a substrate using a plasma chemical deposition process, such as PECVD. The material of the substrate may be chosen to provide for desired mechanical and electrical properties, such as conductivity and rigidity. In one embodiment of the invention, the substrate is made of an electrically insulating material, such as a glass, quartz, or ceramic plate. Alternatively, the substrate may comprise a metal or metal alloy. Persons of skill in the art will appreciate that any of a variety of materials may be selected for the substrate without departing from the scope of the invention.

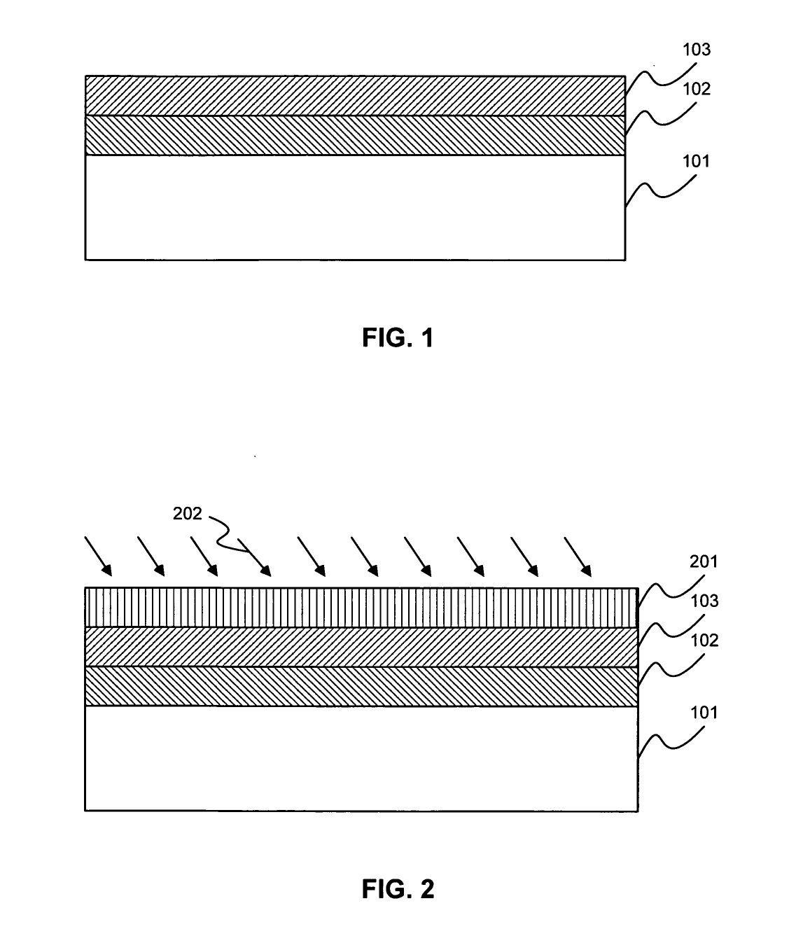

Reference will now be made to FIG. 1, which illustrates a cross-sectional view of a substrate 101 for use in the formation of carbon nanotubes in accordance with an embodiment of the invention. To facilitate the formation of the carbon nanotubes thereon, the upper surface of the substrate 101 may be coated with a catalytic metal layer 103 of a predetermined thickness, as shown in FIG. 1. This catalytic layer 103 may comprise one or more of the transition group metals, including, without limitation, nickel, cobalt, and iron. Alternatively, the catalytic material 103 may comprise an alloy of one or more of those metals. Various methods for coating substrate with catalytic layers of predetermined thickness are well known to persons of skill in the art. One such widely used method is a sputtering deposition process. In one embodiment, the thickness of the catalytic layer 103 is within the range of about 1 nm to about 100 nm.

In one embodiment, an additional buffer layer 102 is disposed between the substrate 101 and the catalytic layer 103. The buffer layer 102 prevents diffusion between the catalytic layer 103 and the substrate 101. In one embodiment of the invention, the buffer layer 102 is formed of a metal, such as molybdenum, titanium, titanium tungsten, titanium nitride, an alloy of titanium, an alloy of titanium tungsten, or an alloy of titanium nitride. Once the catalytic layer 103 and the buffer layer 103 are formed on the substrate 101, the substrate 101 is placed into a plasma process chamber, where the nanotube layer growth is performed.

In one embodiment, before the carbon nanotube layer 201 is grown, the catalyst layer 103 is granularized into nano-sized particles to facilitate the growth of nanotubes 201 on the catalyst layer 103. This granularization step is performed before the nanotubes 201 are grown. To granularize the catalyst layer 103, the substrate is exposed to a granulation gas, which causes patterning of the catalyst layer into nano-sized particles. In this phase, the catalyst layer 103 is granularized into multiple round shapes and randomly spread over the buffer layer 102. Having round shaped nano-sized particles enhances the density of carbon nanotube formed on each catalyst particle.

In one embodiment, the granule size of the catalyst particles ranges from about 1 nm to about 200 nm, and the granule density is in the range of about 10⁸/cm² to about 10¹¹/cm². In one embodiment, during the granulation phase, the reaction surface of the catalyst layer 103 is increased as round catalyst particles form from the originally flat catalyst layer 103. The resulting three-dimensional surface of the catalyst particles enhances the growing of the carbon nanotubes and helps in the diffusion of the carbon radical or the plasma to the catalyst layer 103, reducing the temperature at which the carbon nanotubes may be formed. After the granulation phase, the plasma chamber is purged with nitrogen (N₂) gas, argon (Ar) gas, Helium (He) gas, or any other suitable gas, and the chamber is then evacuated. The substrate is then placed in the chamber and heated to a temperature of about 400° C. to about 600° C.

FIG. 2 illustrates a cross-sectional view of a substrate during a growth stage of the carbon nanotube formation process. As illustrated, a deposition plasma 202 is produced by a plasma source in the chamber. This deposition plasma 202 results in the formation of a carbon nanotube layer 201. To facilitate the growth process, the substrate 101 and the ambient gas in the plasma process chamber may be heated to a temperature within a range of about 400° C. to about 600° C. In one embodiment of the present invention, the plasma density for growing the carbon nanotubes is in the range of about 10¹⁰/cm³ to about 10¹²/cm³.

In one embodiment of the invention, the deposition plasma 202 is produced by an inductively coupled plasma or a microwave plasma chanber, which is preferably capable of generating a high-density plasma. The source gas for the deposition plasma 202 may be a hydrocarbon containing gas, and it may have a hydrogen-containing gas as additive. The presence of the additive gas in the plasma process chamber facilitates the purification of the grown nanotube structures during a later purification process step without the need to purge the process chamber. In another embodiment, the deposition plasma 202 is produced by a capacitively coupled plasma device, which is preferably capable of generating a high-density plasma.

In one embodiment of the present invention, the plasma source gas for growing the carbon nanotubes may include CH₄ and/or C₂H₂. The temperature range of the substrate during the growing of the carbon nanotubes typically ranges between about 400° C. to about 600° C., and the plasma gas pressure ranges between about 500 mTorr to about 5000 mTorr. The carbon nanotube layer 201 is grown in the plasma process chamber to a predetermined thickness, although the nanotube layer 201 thickness is generally not linear with the time of growth.

To improve the vertical growth of the carbon nanotubes, a negative voltage bias may be applied to the substrate 101 during the growth stage of the carbon nanotubes. In one embodiment, the applied negative voltage is between about 50 and about 600 Volts. Preferably, the carbon nanotubes are grown perpendicular from the substrate's surface. The angle of the grown carbon nanotubes from the normal axis of the substrate is preferably less than 45 degrees. After the carbon nanotubes are grown, the granular particles from the catalyst layer may be on the bottom and/or top of the carbon nanotubes, and these particles are preferably removed.

U.S. application Ser. No. 10/889,807, filed Jul. 12, 2004, the contents of which are incorporated by reference in its entirety, describes a process for growing carbon nanotubes on a substrate using PECVD. In one embodiment, the carbon nanotube layer 201 is grown according to one of the processes described therein.

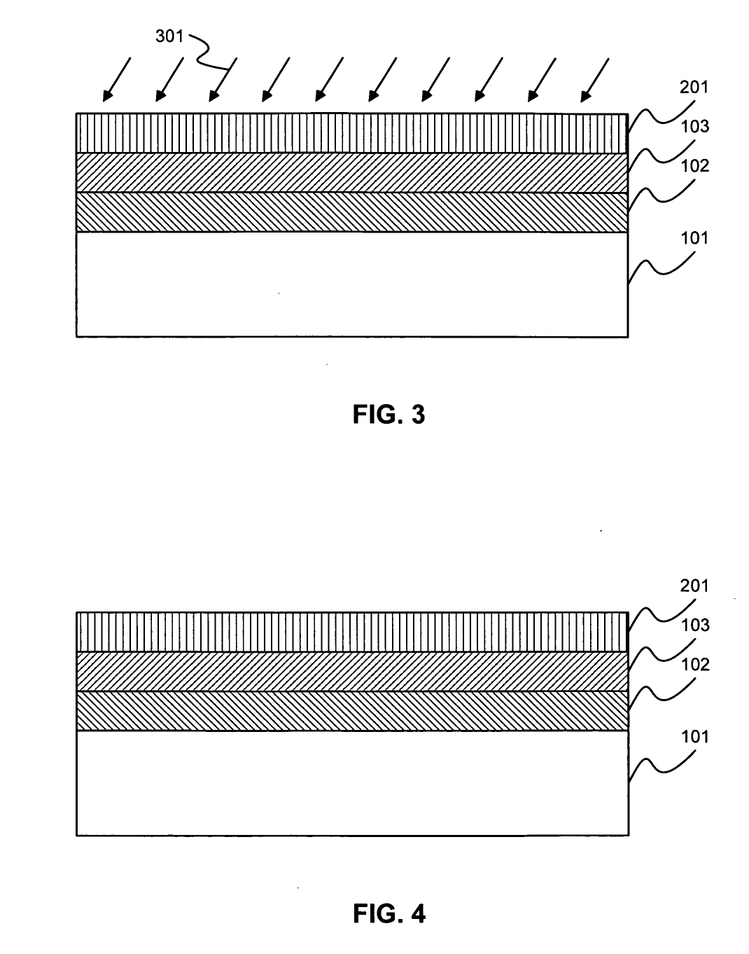

After the nanotubes have been grown, a purification step is performed on the newly formed nanotube structures in one embodiment. The purification step is not required, but the purification step may beneficially remove graphite and other carbon particles from the walls of the grown carbon nanotubes, as well as control the physical dimensions or physical characteristics of the carbon nanotubes. FIG. 3 illustrates a cross-sectional view of a substrate during an intermediate purification stage of the carbon nanotube formation process. As illustrated, a purification plasma 301 is produced by a plasma source within the chamber. In one embodiment of the invention, the purification is performed with the plasma 301 at the same temperature as the substrate 101.

In one embodiment, an additive hydrogen containing gas is used as the plasma source gas during the purification stage. The additive hydrogen containing gas may comprise H₂, NH₃, or a mixture of H₂ and NH₃. Because the source gas for the purification plasma is added as an additive to the source gas for the chemical plasma deposition, the grown carbon nanotubes are purified by reacting with the continuous plasma, which is sustained in the plasma process chamber. This eliminates the need to purge and evacuate the plasma process chamber as well as to stabilize the pressure with the purification gas. After the carbon nanotube layer 201 is purified with the purification plasma 301, the nanotube growth and purification steps may be repeated. FIG. 4 illustrates a cross-sectional view of a substrate 101 having a carbon nanotube layer 201 grown and purified in accordance with an embodiment of the invention described herein.

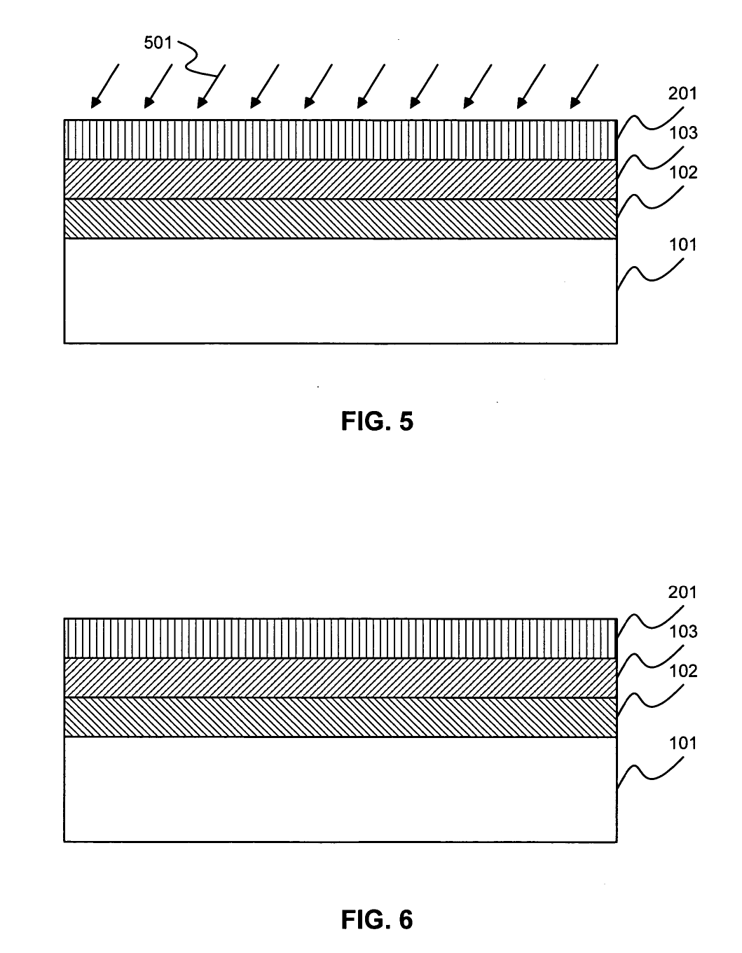

After the nanotubes have been grown in the described manner, a post-treatment step is performed on the newly formed (and optionally purified) carbon nanotube layer 201. Beneficially, the post-treatment removes graphite and other carbon particles from the walls of the grown nanotubes, and it controls the diameter of the carbon nanotubes. FIG. 5 illustrates a cross-sectional view of the substrate during a post-treatment stage of the carbon nanotubes formation process. As illustrated, a post-treatment plasma 501 is produced by a plasma source in the process chamber. In one embodiment, the post-treatment is performed with the plasma 501 at the same temperature as the substrate 101.

In one embodiment, an additive hydrogen containing gas is used as the plasma source gas during the post-treatment stage. The hydrogen containing gas may comprise H₂, NH₃, or a mixture of H₂ and NH₃. During the transition from the nanotube growth step (and optional purification step) to the post-treatment step, the pressure in the plasma process chamber may be stabilized with the post-treatment gas without shutting off the plasma in the chamber. This eliminates the need to purge and evacuate the plasma process chamber. FIG. 6 illustrates a cross-sectional view of a substrate 101 having a carbon nanotube layer 201 grown and post-treated in accordance with an embodiment of the invention described herein. The highly uniform carbon nanotubes grown on the structure shown in FIG. 6 may be used in a number of applications, such as electron emitters in an electron emissive device (e.g., a field emissive display device).

In another embodiment, after the post-treatment of the carbon nanotube layer 201, the pressure in the chamber may again be stabilized with the nanotube growing gas, and the nanotube growth may be repeated. By repeating the entire process of carbon nanotube growth (which may involve intermediate purification steps) and post-treatment, a more uniform carbon nanotube layer can be formed.

In one embodiment, once a first iteration of the growth is performed, the average value of the thickness of the carbon nanotube layer 201 (or length/height of the nanotubes) is assessed. Based on that assessment, the post-treatment step is designed so that the post-treatment step will “etch-off” the carbon nanotube layer 201 (i.e., remove carbon nanotube matter) to about half of that average value. This etching causes any carbon nanotubes in the layer 201 to be shortened to about that average length, whereas the nanotubes shorter than the average would remain intact. In this way, the variance in the length of the carbon nanotubes is reduced. In one embodiment, the time of the post-treatment etching step is adjusted so that the carbon nanotubes are reduced to the desired length.

Once the nanotube growth and post-treatment process is completed, another iteration may be run. For example, another growth step is performed (which may also include intermediate purification steps), causing the carbon nanotubes to lengthen. Once the nanotubes are lengthened through the additional growth process, another post-treatment step is performed. This subsequent post-treatment step preferably performs a lighter etching of the carbon nanotube layer 201, removing less of the carbon nanotube matter. In one embodiment, an assessment is made to determine the new average length of the carbon nanotubes. The post-treatment step is then designed so that it etches off about 20% of the new average height. It can be appreciated that this iterative process results in a carbon nanotube layer 201 having more uniform height (i.e., nanotube length), which improves the operation of the nanotubes in an electrical device.

In another embodiment, a plurality of iterations as described above may be run to achieve a highly uniform carbon nanotube layer 201. In each successive iteration, the amount of etching performed by the post-treatment step can be reduced.

It should be understood that processes and techniques described herein are not inherently related to any particular apparatus and may be implemented by any suitable combination of components. Moreover, various types of general purpose devices may be used in accordance with the teachings described herein. It may also prove advantageous to construct specialized apparatus to perform the method steps described herein. Accordingly, the foregoing description of the embodiments of the invention has been presented for the purpose of illustration; it is not intended to be exhaustive or to limit the invention to the precise forms disclosed. Persons skilled in the relevant art can appreciate that many modifications and variations are possible in light of the above teachings. It is therefore intended that the scope of the invention be limited not by this detailed description, but rather by the claims appended hereto.

1. A method of forming carbon nanotubes in a chamber, the method comprising:
growing a plurality of carbon nanotubes by chemical vapor deposition using a plasma;
without shutting off the plasma after the carbon nanotubes are grown, post-treating the grown carbon nanotubes by etching to shorten at least some of the carbon nanotubes; and
repeating the growing and post-treating steps.

2. The method of claim 1, wherein a first iteration of the post-treating step etches more carbon nanotube length than a second iteration of the post-treating step.

3. The method of claim 1, wherein the post-treating comprises:
determining an average length of the carbon nanotubes; and
shortening at least some of the carbon nanotubes so that substantially all of the carbon nanotubes are less than or equal to a predetermined fraction of the average length.

4. The method of claim 3, wherein in a first iteration of the post-treating step, the predetermined fraction is about 50%.

5. The method of claim 3, wherein in a second iteration of the post-treating step, the predetermined fraction is about 20%.

6. The method of claim 3, wherein the predetermined fraction decreases with successive iterations of the post-treating step.

7. The method of claim 1, further comprising, before each post-treating step:
purifying the grown carbon nanotubes by plasma etching using a purification gas; and
repeating the growing and purifying steps, without evacuating the chamber and without turning off the plasma between the growing and purifying steps.

8. A method of forming carbon nanotubes in a chamber, the method comprising:
growing a plurality of carbon nanotubes by plasma enhanced chemical vapor deposition;
a step for post-treating the grown carbon nanotubes to reduce a variance in length of the grown carbon nanotubes, and without turning off the plasma after the carbon nanotubes are grown.

9. A method of forming carbon nanotubes in a chamber, the method comprising repeating the method of claim 8.

10 An electron emissive device comprising a plurality of carbon nanotubes substrate by the method of any one of the preceding claims.
